(19) United States
(12) Patent Application Publication
(10) Pub. No.: US 2026/0293533 A1
(43) Pub. Date: Sep. 24, 2026

(54) MAGNETIC SWITCHING OF 2D DILUTE MAGNETIC SEMICONDUCTOR MONOLAYERS ABOVE ROOM TEMPERATURE IN THE ABSENCE OF AN EXTERNAL MAGNETIC FIELD

(71) Applicant: THE TRUSTEES OF THE STEVENS INSTITUTE OF TECHNOLOGY, HOBOKEN, NJ (US)

(72) Inventors: EUI-HYEOK YANG, FORT LEE, NJ (US); SIWEI CHEN, JERSEY CITY, NJ (US); MENGQI FANG, HOBOKEN, NJ (US); ZITAO TANG, JERSEY CITY, NJ (US)

(21) Appl. No.: 19/560,913

(22) Filed: Mar. 9, 2026

Related U.S. Application Data
(60) Provisional application No. 63/775,453, filed on Mar. 21, 2025.

(51) Int. Cl. H10N 50/85; G11C 11/16; H10N 50/10; H10N 50/20

(52) U.S. Cl. CPC H10N 50/85; G11C 11/161; G11C 11/1673; G11C 11/1675; H10N 50/10; H10N 50/20

(57) ABSTRACT

The disclosed technology includes spin-orbit and orbital torque devices. The device includes a bottom electrode and a free magnetic layer. The bottom electrode is capable of generating spin currents via the spin Hall effect. The free magnetic layer is disposed on the bottom electrode. A magnetization of the free magnetic layer is switchable by the spin currents between, relative to the predetermined state, a parallel state and an antiparallel state in the absence of an external magnetic field. The free magnetic layer includes a van der Waals dilute magnetic semiconductor having a Curie Temperature greater than room temperature.

### CROSS REFERENCE TO RELATED APPLICATIONS

This application claims the benefit of priority under 35 U.S.C. § 119 to prior filed U.S. Provisional Patent Application No. 63/775,453, filed Mar. 21, 2025 (Attorney Docket No.: 148841.000009 (FY25-001)), the entire contents of which is hereby incorporated by reference in its entirety as if set forth in full herein.

### FIELD

The present technology relates generally to spin-orbit torque (SOT) and orbital torque (OT) devices with a free magnetic layer that can switch magnetization at or above room temperature in the absence of an external magnetic field for non-volatile memory technology.

### BACKGROUND

Semiconductors possess enormous utility in the computing fields, and electronics in general. Specifically, a diluted magnetic semiconductor (DMS) is a class of semiconductor material that exhibits both ferromagnetism and semiconductor properties, which include Mn-doped Pb₁₋ₓSnₓTe and GaAs among others. Of particular interest, DMS materials allow for the manipulation of quantum spin states, which makes them promising candidates for a variety of applications.

In spintronics memory, like spin-orbit-torque (SOT)-magnetic random-access memory (MRAM), the memory cells store data by manipulating the orientation of electron spins rather than using electron charges, as in traditional semiconductor memory. Each memory cell includes a magnetic tunnel junction (MTJ), which typically includes two ferromagnetic layers (e.g., a fixed layer and a free layer) separated by a non-magnetic spacer layer. SOT is used to switch the magnetization direction of the magnetic layers in the MTJ. This torque is induced by applying an electric current to a heavy metal layer or topological insulator adjacent to the MTJ. The direction of the current and the spin-orbit coupling in the heavy metal generate a torque that can flip the magnetization of one of the ferromagnetic layers. A short pulse of current is applied to the heavy metal layer to write data. The spin-orbit torque causes the magnetization direction of one of the ferromagnetic layers (typically the free magnetic layer) to switch, representing either a ‘0’ or ‘1’ state. A small voltage is applied across the MTJ to read data. The resistance of the tunnel junction varies depending on whether the magnetizations of the two ferromagnetic layers are parallel (low resistance) or antiparallel (high resistance).

Two-dimensional (2D) van der Waals (vdW) magnets hold potential for use in spintronics, which results from the absence of dangling bonds and decreased atom intermixing near the interface at the heterostructure surface. The spintronics of 2D vdW magnets are particularly beneficial because of their strong perpendicular magnetic anisotropy (PMA), paving the way toward versatile manipulation of magnetic ordering via current-induced spin-orbit torque (SOT). SOT switching involves applying a current pulse that induces torque on the magnetization of materials through spin-orbit interactions, efficiently altering the magnetic states of magnetic layers. The spin-orbit interaction is facilitated by integrating 2D magnets with materials exhibiting robust spin-orbit coupling (SOC), such as topological insulators or heavy metals. The synergy between these materials and vdW magnets may significantly enhance the SOT efficiency, attributed to high-quality interface, high interfacial spin transmission, and inherently low magnetic damping in vdW magnets.

To achieve high efficiency in SOT switching, it is crucial to select high spin transparency materials and minimize the thickness of the magnetic layer to reduce magnetic damping and saturation magnetization. Furthermore, the ability to achieve SOT switching without an external magnetic field is essential for practical applications. Room temperature, field-free SOT switching can be achieved using WTe₂, combined with vdW materials. These vdW magnets can be synthesized via flux crystal growth or molecular beam epitaxy, often followed by mechanical exfoliation.

To enhance the system's energy efficiency, thinning these 2D magnets may be required. However, as the number of layers is reduced to achieve thinner structures, their Curie temperature significantly drops, well below room temperature. Furthermore, the surfaces of these materials are unstable in air. This thickness limitation presents a significant challenge for low-current-density, field-free SOT switching using vdW monolayers.

Accordingly, there is a need for a device for practical SOT applications that is stable and can switch magnetization, via SOT, above room temperature without an external magnetic field.

### SUMMARY

Conversely, substitutional doping of monolayer transition metal dichalcogenides (TMDs), including MoS₂ and WSe₂, synthesized via chemical vapor deposition (CVD), thus providing ultimate scalability, enables the formation of 2D DMSs. These DMSs exhibit ferromagnetic properties above room temperature, even at monolayer thicknesses, which makes them ideal candidates for SOT materials at the true 2D limit (i.e., atomically thin monolayers).

Specifically, and for example, the disclosed technology shows field-free, deterministic, and nonvolatile SOT switching of perpendicular magnetization in a monolayer iron-doped MoS₂ (Fe:MoS₂), at up to 380 K with a current density of ~7×10⁴ A cm⁻¹. Specifically, the disclosed technology employs (i) in situ doping of Fe into monolayer MoS₂ via, e.g., chemical vapor deposition and (ii) geometry-induced strain in the crystal to break the rotational switching symmetry in Fe:MoS₂, which promotes field-free SOT switching by generating out-of-plane spins via spin-to-spin conversion. This field-free SOT application using a 2D ferromagnetic monolayer provides a new pathway for developing highly power-efficient spintronic memory devices, such as SOT-MRAM.

There is provided, in accordance with the disclosed technology, a spin-orbit-torque (SOT) device including a bottom electrode and a free magnetic layer. The bottom electrode is capable of generating spin currents via the spin Hall effect (SHE). The free magnetic layer is disposed on the bottom electrode. A magnetization of the free magnetic layer is switchable by the spin currents between, relative to the predetermined state, a parallel state and an antiparallel state in the absence of an external magnetic field. The free magnetic layer includes a van der Waals (vdW) dilute magnetic semiconductor having a Curie Temperature greater than room temperature.

There is provided, in accordance with the disclosed technology, a SOT device including a bottom electrode and a free magnetic layer. The bottom electrode includes a heavy metal layer capable of generating spin currents via the spin Hall effect (SHE). The free magnetic layer is disposed on the bottom electrode. A magnetization of the free magnetic layer is switchable by the spin currents between, relative to the predetermined state, a parallel state and an antiparallel state. The free magnetic layer includes molybdenum disulfide including iron dopants (Fe:MoS₂).

There is provided, in accordance with the disclosed technology, a method of switching a resistance state of a free magnetic layer in an external environment. The external environment has a temperature at or greater than room temperature. The method includes applying a current through a bottom electrode in a direction that is parallel to a plane of the free magnetic layer that is disposed on the bottom electrode. The method includes generating spin currents via the SHE. The method includes switching, via the spin currents and in the absence of an external magnetic field, a magnetization direction of the free magnetic layer.

There is provided, in accordance with the disclosed technology, a method of making a SOT device. The method includes producing a first semiconductor material. The producing step includes (i) growing a two-dimensional transition metal dichalcogenide monolayer on a first substrate, and (ii) adding a dopant to the monolayer while the monolayer is being grown on the first substrate. The method includes patterning a heavy metal layer onto a second substrate; transferring the first semiconductor material onto the heavy metal layer. The method includes inducing uniaxial strain in the first semiconductor material in a direction that is (i) perpendicular to a height direction of the heavy metal layer, and (ii) perpendicular to a direction in which write current is configured to flow through the heavy metal layer.

### BRIEF DESCRIPTION OF THE DRAWINGS

FIG. 1 is a schematic pictorial illustration of a flow diagram showing a manufacturing process for materials made in accordance with the disclosed technology;

FIG. 2A is a schematic pictorial illustration showing a top view of the crystal structure of a two-dimensional transition metal-doped transition metal dichalcogenide monolayer (e.g., Fe:MoS₂ monolayer) prepared in accordance with the disclosed technology;

FIG. 2B is a schematic pictorial illustration showing a side view of the crystal structure of FIG. 2A, in accordance with the disclosed technology;

FIG. 3 is a schematic pictorial illustration showing another top view of the crystal structure of a Fe:MoS₂ monolayer of FIG. 2A, depicting the crystal structure undergoing uniaxial strain in the armchair and zigzag direction, in accordance with the disclosed technology;

FIG. 4 is a schematic pictorial illustration showing the Fe:MoS₂ monolayer transferred onto a bottom electrode (e.g., platinum), in accordance with the disclosed technology;

FIGS. 5A-5B are schematic pictorial illustrations showing a Fe:MoS₂/bottom electrode heterostructure with induced axial strain in the Fe:MoS₂, in accordance with the disclosed technology;

FIG. 6 is a schematic pictorial illustration of an optical image showing the Fe:MoS₂ monolayer transferred onto the bottom electrode, in accordance with the disclosed technology;

FIG. 7A is a schematic pictorial illustration showing the Fe:MoS₂ monolayer transferred onto the bottom electrode with uniaxial strain in the zigzag direction, in accordance with the disclosed technology;

FIG. 7B is a schematic pictorial illustration showing the Fe:MoS₂ monolayer transferred onto the bottom electrode with uniaxial strain in the armchair direction, in accordance with the disclosed technology;

FIG. 8 is a schematic pictorial illustration showing a cross-sectional view of a 2D SOT-MRAM device made in accordance with the disclosed technology;

FIG. 9A is a schematic pictorial illustration showing a layout of a 2×1 SOT-MRAM unit, in accordance with the disclosed technology;

FIG. 9B is a schematic pictorial illustration showing a cross-sectional view of a spin-logic device based on MRAM unit, in accordance with the disclosed technology;

FIG. 9C is a logic truth table showing an example of the expected MTJ resistance, in accordance with the disclosed technology;

FIG. 10 is a flow diagram showing an exemplary method of making a SOT device, in accordance with the disclosed technology; and

FIG. 11 is a flow diagram showing an exemplary method of using a SOT device, in accordance with the disclosed technology.

### DETAILED DESCRIPTION

The following detailed description should be read with reference to the drawings, in which like elements in different drawings are identically numbered. The drawings, which are not necessarily to scale, depict selected examples and are not intended to limit the scope of the present disclosure. The detailed description illustrates by way of example, not by way of limitation, the principles of the disclosed technology. This description will clearly enable one skilled in the art to make and use the disclosed technology, and describes several embodiments, adaptations, variations, alternatives and uses of the disclosed technology, including what is presently believed to be the best mode of carrying out the disclosed technology.

As used herein, the terms “about” or “approximately” or “generally” for any numerical values or ranges indicate a suitable dimensional tolerance that allows the part or collection of components to function for its intended purpose as described herein. More specifically, “about” or “approximately” may refer to the range of values ±20% of the recited value, e.g. “about 90%” may refer to the range of values from 71% to 110%.

As used herein, the term “room temperature” refers to a temperature range of approximately 20° Celsius (C) to 25° C. (or 293 Kelvin (K) to 298 K).

In one example, the presently disclosed technology allows for creation of a 2D DMS that can be realized via in situ synthesis of iron-doped MoS₂(Fe:MoS₂) monolayers. In alternate examples, other doped TMD compounds may be produced, such as those comprising WS₂, MoSe₂ and WSe₂, using the methods of the disclosed technology. In one example, the in situ doping and the growth of the material are simultaneously achieved via LPCVD growth. In one example, Fe:MoS₂ monolayers are grown onto an SiO₂ substrate in this manner, while FeCl₃ (anhydrous) on a Si substrate can also be used as the Fe source for doping.

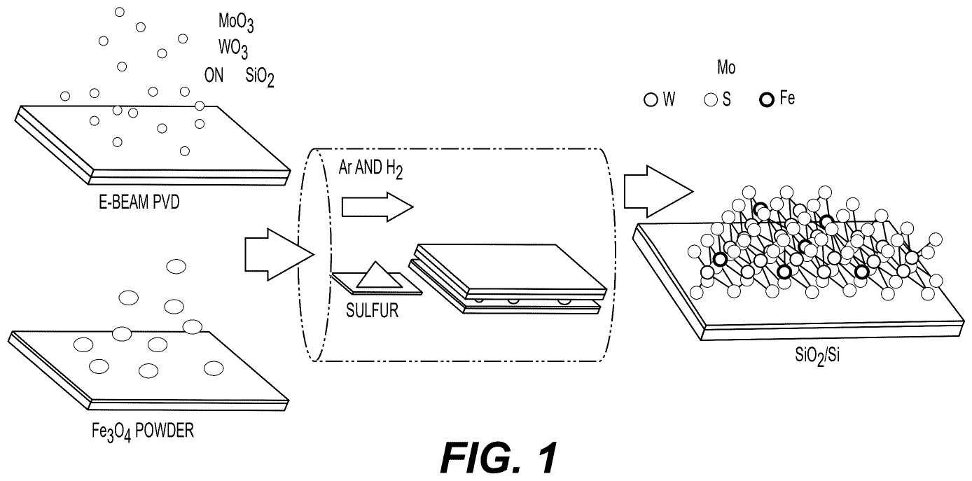

FIG. 1 is a flow diagram showing an exemplary manufacturing process for Fe:MoS₂ monolayers made in accordance with the present disclosure. In one example, MoS₂ monolayers are synthesized via low-pressure chemical vapor deposition (LPCVD). For growth, a thin layer of MoO₃ is deposited via Joule heating thermal evaporation onto a Si substrate covered with thermal oxides of a suitable thickness (e.g., a 300 nm thick thermal oxide layer). Next, another SiO₂/Si substrate directly contacts the MoO₃-deposited substrate during growth. The substrate used can be varied (e.g., SiC or sapphire or any appropriate dielectric layer), or the doped monolayer (discussed in greater detail in the following paragraph) can be transferred to another desired substrate when formed, as appropriate to the intended application.

To substitutionally dope Fe into the MoS₂ monolayers, the following sequence can be employed. Fe₃O₄ particles are applied to the SiO₂/Si substrate before contacting the MoO₃-deposited substrate. For a uniform distribution of Fe₃O₄ particles, the substrate can be washed with deionized (DI) water so that a thin layer of water is created on the SiO₂ surface, prior to applying the Fe₃O₄ particles. Subsequently, the Fe₃O₄ particles are applied onto the surface of the substrate. The substrate is then annealed at 110° C. or above for 5 to 10 minutes (e.g., 110° C. for 5 minutes) on a hot plate. During the growth, the furnace can be heated at a ramp rate of 18° C./min and held at 850° C. for 15 to 20 minutes (e.g., 15 minutes). During the heating procedure, Ar gas can be initially supplied at a rate of 25 to 30 standard cubic centimeters per minute (sccm) (e.g., 30 sccm) during heating until the temperature reached 300° C. to 400° C. (e.g., 300° C.). Then, H₂ gas can introduced at a rate of 15 to 20 sccm (e.g., 15 sccm) as the temperature increased to 750° C. to 770° C. (e.g., 760° C.). In some examples, a ratio of Ar to H₂ is between 3:2 to 2:1. Sulfur can be added to the furnace once the temperature reached 780° C. to 800° C. (e.g., 790° C.). After the growth, Fe:MoS₂ monolayers are obtained.

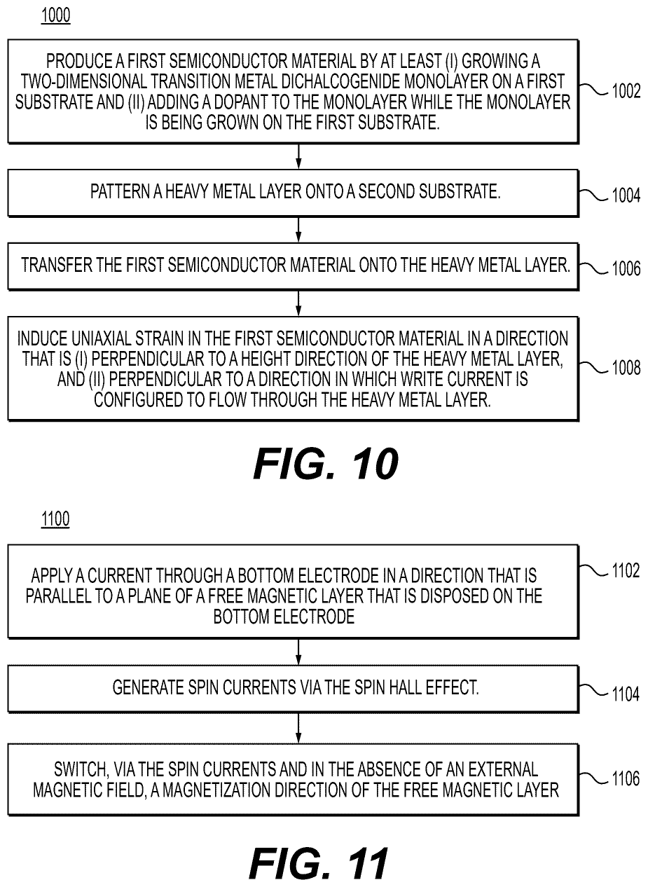

Therefore, as seen in FIG. 10, a method 1000 of forming a SOT device generally includes producing 1002 a first semiconductor material. This production step 1102 includes growing a two-dimensional transition metal dichalcogenide monolayer on a first substrate and adding a dopant to the monolayer while the monolayer is being grown on the first substrate, as discussed above.

Substitutional doping of monolayer transition metal dichalcogenides (TMDs), including MoS₂ and WSe₂, synthesized via chemical vapor deposition (CVD), which provides ultimate scalability, enables the formation of 2D DMSs. Specifically, 2D transition metal-doped transition metal dichalcogenides (which constitutes a soft magnet) are obtained by the aforementioned method. These DMSs exhibit ferromagnetic properties above room temperature, even at monolayer thicknesses, which makes them ideal candidates for SOT materials at the true 2D limit (i.e., atomically thin monolayers). While the following description focuses primarily on the substitutional doping of MoS₂, those skilled in the art will appreciate that WSe₂ including Fe dopants (or, alternatively, WS₂ or MoSe₂ including Fe dopants) can be employed in a similar manner without departing from the spirit and scope of the present disclosure.

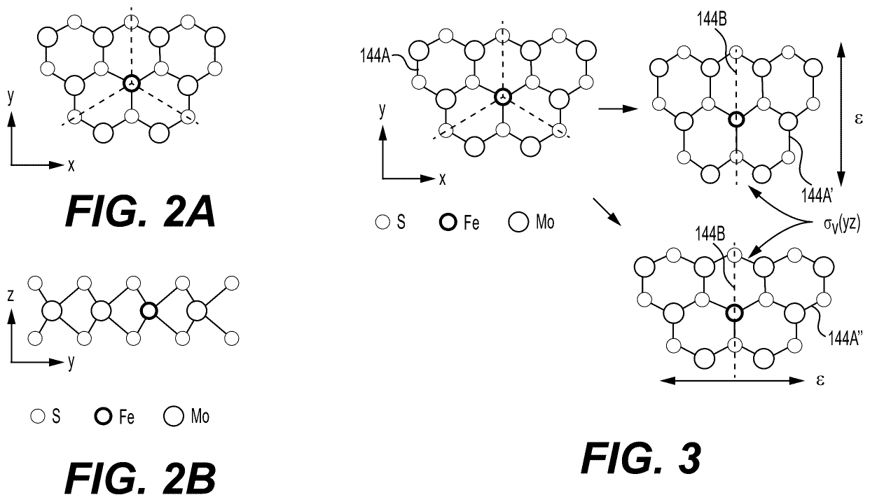

FIGS. 2A and 2B show schematics of the crystal structures of a Fe:MoS₂ along the x-y plane (FIG. 2A) and the y-z plane (FIG. 2B). These figures illustrate that Fe atoms substitute for Mo sites within the lattice.

Reference is now made to FIGS. 3-5B. Field-free SOT switching of perpendicular magnetization can be facilitated by utilizing low-symmetry crystals with, at most, one mirror symmetry. Pristine MoS₂ exhibits threefold rotational symmetry. Therefore, the disclosed technology applies uniaxial strain along the y-axis or x-axis (as seen in FIG. 3) to disrupt the rotational symmetry in the hexagonal lattice 144A, retaining only the y-z mirror plane symmetry, σᵥ (yz)(z represents the axis orthogonal to the plane defined by the x- and y-axes), as shown in FIG. 3. Uniaxial strain along the y-axis is represented by the distorted hexagonal lattice 144A′ in the upper right hand of FIG. 3 (which is representative of uniaxial strain along the armchair axis/direction), while uniaxial strain along the x-axis is represented by the hexagonal lattice 144A″ in the lower right hand of FIG. 3 (which is representative of uniaxial strain along the zigzag axis/direction). The vertical dashed line 144B (also referred to herein as the armchair direction axis) denotes the preserved mirror symmetry in the y-z plane σᵥ (yz) under uniaxial armchair strain.

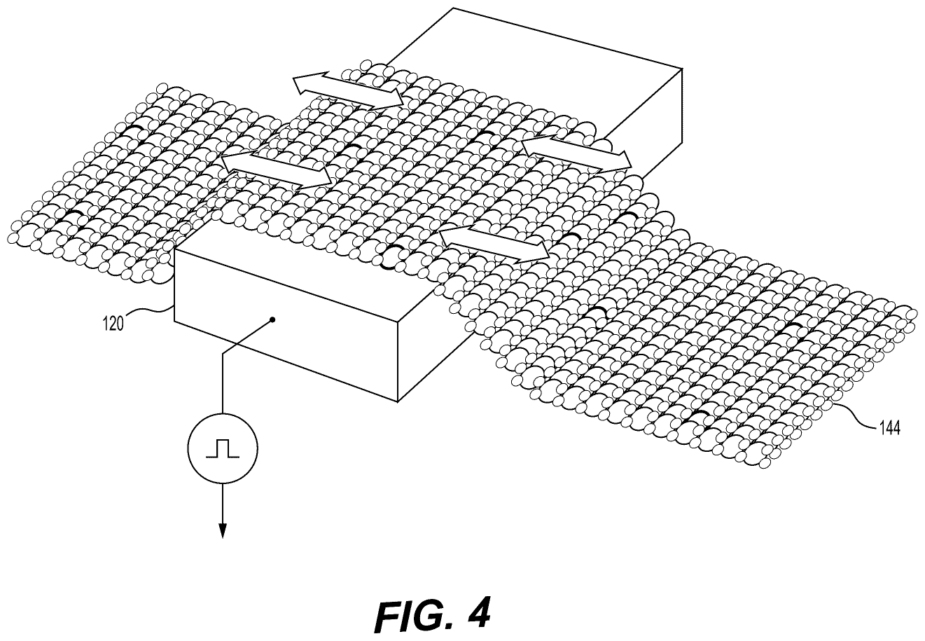

In the present example, as seen in FIG. 4, uniaxial strain is applied by a bottom electrode 120, upon which monolayer Fe:MoS₂ 144 under armchair strain has been transferred. The presently disclosed technology and method employs a Pt Hall bar to demonstrate one example of a bottom electrode 120, forming a Fe:MoS₂/Pt heterostructure. Alternatively, Ta, W or a topological insulator layer can be employed without departing from the spirit and scope of the present disclosure.

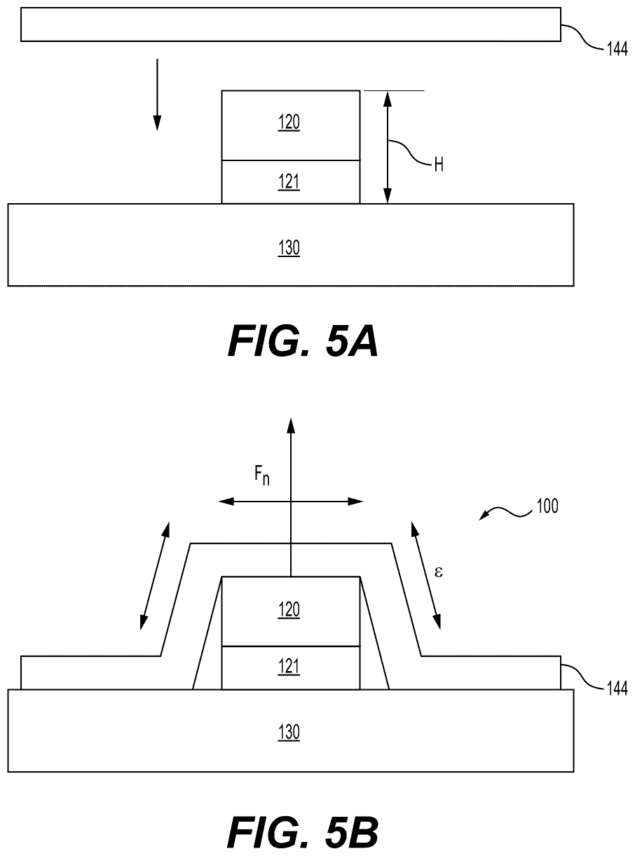

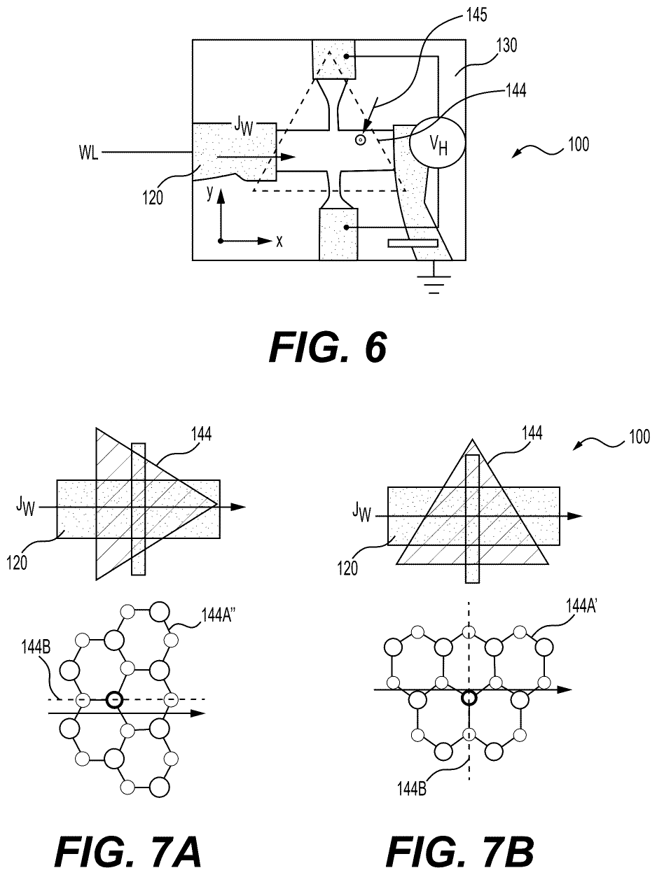

In the present example, the Fe:MoS₂/Pt heterostructure can be formed by the following exemplary method. As seen in FIG. 6 a plurality of Hall bar contacts (Pt/Cr-8/5 nm) (with, e.g., dimensions of 2 μm×5 μm) are patterned on a substrate 130 (e.g., a SiO₂/Si substrate) via e-beam lithography, with Cr functioning as an adhesion layer 121 (FIG. 5A). In the present example, four Hall bar contacts are employed, with one connected to a word line WL that supplies a write current J_{w} (also referred to as the charge current) with two contacts being used to read the Hall voltage V_{H} across the heterostructure. The substrate 130 is spin-coated with PMMA and then baked at 180° C. for 90 seconds. Subsequently, the photoresist is exposed to the e-beam and developed using a 3:1 mixture of 4-methyl-2-pentanone (MIBK) and 2-propanol (IPA). The Pt/Cr layers 120, 121 are deposited onto the patterned photoresist layer via, e.g., e-beam evaporation. The photoresist is removed through a lift-off process involving rinsing with, e.g., acetone and IPA to define Pt/Cr electrodes 120 (see FIG. 6) on the substrate 130.

Therefore, as seen in FIG. 10, a method 1000 of forming a SOT device generally includes patterning 1004 a heavy metal layer onto a substrate (different from the substrate discussed in the producing step 1002).

Fe:MoS₂ monolayers grown on SiO₂ (discussed above with respect to FIG. 1) can be coated with a thin layer of PMMA (e.g., 950 A4) using a dropper. The chip is left under ambient conditions to dry for, e.g., 60 min. The chip is floated in a basic solution, such as 10% KOH (aq), for, e.g., 10 min, after which the Si substrate sinks in the 10% KOH (aq) due to SiO₂ etching, leaving the PMMA/MoS₂ floating on the surface of the KOH solution. Next, the PMMA/MoS₂ is cleaned in DI water, is scooped using another substrate (i.e., a target substrate), and is dried under ambient conditions for, e.g., 1 hour. A PMMA film with a Fe:MoS₂ crystal is attached beneath poly(dimethylsiloxane) (PDMS) and stamped with Fe:MoS₂ 144 aligned atop the Pt electrode 120. The PMMA is removed using, e.g., warm acetone, followed by an IPA rinse. The fabricated Fe:MoS₂/Pt SOT device 100 (FIG. 5B) is loaded in a furnace with a tube (e.g., a 2″ quartz tube) and annealed at, e.g., 120° C. for 20 min to enhance adhesion. The fabricated Fe:MoS₂/Pt SOT device 100 can then be soaked in 2-hour chloroform (CHCl₃) at room temperature to remove organic residues thoroughly.

Therefore, as seen in FIG. 10, a method 1000 of forming a SOT device generally includes transferring 1006 the first semiconductor material (e.g., the Fe:MoS₂ in the present example) onto the heavy metal layer (e.g., the Pt electrode 120 in the present example).

The step height H of the Pt Hall bar 120, as illustrated in FIGS. 5A-5B, induces uniaxial strain (e) in the monolayer Fe:MoS₂ 144 perpendicular to the edge of the Pt Hall bar 120 when the monolayer Fe:MoS₂ 144 is transferred onto it, as seen from FIG. 5A to FIG. 5B. As seen in FIG. 5B, the strain in the monolayer Fe:MoS₂ 144 where it sits on the Pt Hall bar 120 is orthogonal to the height direction of the Pt Hall bar height H (see FIG. 5A). This facilitates geometry-induced strain to break the inversion symmetry of the material as well as twisted bilayer DMS to induce distinguishable handedness (i.e., chirality).

Therefore, as seen in FIG. 10, a method 1000 of forming a SOT device generally includes inducing 1008 uniaxial strain in the first semiconductor material (e.g., the Fe:MoS₂ in the present example).

To determine the lattice orientation of Fe:MoS₂, thus controlling the strain direction, the presently disclosed technology employs the edge morphology of triangular island single crystals 144, as shown in FIGS. 6-7B. FIGS. 3 and 6-7B show a schematic representation of the strained Fe:MoS₂ lattice structure along the armchair (e.g., upper right of FIG. 3, FIG. 6, and FIG. 7B) and zigzag directions (e.g., bottom right of FIG. 3 and FIG. 7A), effectively modulating the crystal symmetry.

In monolayer MoS₂, covalent bonding between Mo and S is very sensitive to in-plane uniaxial strain due to the strain-induced change in the coupling between the Mo atom d orbital and S atom p orbital. For MoS₂, in the absence of strain, the E_{2g}¹ mode intensities have negligible change. This trend is also present in monolayer Fe:MoS₂ transferred onto a flat bottom electrode, e.g., a flat SiO₂ surface, for which the E_{2g}¹ mode intensity difference is less than 5%.

The alteration in crystal symmetry can be confirmed by analyzing the angle-resolved polarized Raman spectra of monolayer Fe:MoS₂ 144 transferred onto the bottom electrode 120 (e.g., as discussed above, a Pt Hall bar). The polar Raman laser spot is indicated with the arrow 145 in FIG. 6. The monolayer Fe:MoS₂ 144, when transferred to the Pt Hall bar 120, comprises a E_{2g}¹ peak with a distinct polarity that confirms the occurrence of uniaxial strain, which in turn modulates the crystal symmetry of Fe:MoS₂. This symmetry alteration promotes field-free SOT switching by generating out-of-plane spin accumulation when current is injected along the zigzag axis (x-axis) at the Fe:MoS₂/Pt interface. In some examples, the Fe:MoS₂ 144 transferred on the Hall bar 120 has approximately 3% tensile strain.

The most pressing issue for SOT-MRAM is balancing higher packaging density and lower power consumption while maintaining or improving speed and reliability. The disclosed technology utilizes a vdW dilute magnetic semiconductor (DMS), Fe:MoS₂ (as detailed above), for a field-free, non-volatile SOT switching. Its field-free, deterministic operation and non-volatile characteristics make it a groundbreaking solution for spintronic applications requiring reliable, low-power, and high-density computing devices.

The presently disclosed technology permits ultralow current-density, field-free, deterministic, non-volatile SOT switching of perpendicular magnetization in a CVD-grown, monolayer Fe:MoS₂ 144. In examples described above, this perpendicular magnetization is achieved by transferring the monolayer Fe:MoS₂ 144 onto a Pt Hall bar 120. Its field-free, deterministic operation and non-volatile characteristics make it a groundbreaking solution for spintronic applications requiring reliable, low-power, and high-density computing devices.

Put another way, as seen in FIG. 6, a SOT device in accordance with the present disclosure includes a bottom electrode 120 and a free magnetic layer 144. The bottom electrode 120 is capable of generating spin currents via the SHE (discussed in greater detail below. The free magnetic layer 144 is disposed on the bottom electrode 120. A magnetization of the free magnetic layer 120 being switchable by the spin currents between, relative to the predetermined state, a parallel state and an antiparallel state. As discussed in greater detail below, the switching occurs in the absence of an external magnetic field, and the free magnetic layer 144 has a Curie Temperature greater than room temperature.

In accordance with the disclosed technology, the PMA in Fe:MoS₂ can be demonstrated by measuring the anomalous Hall effect (AHE) in Fe:MoS₂/Pt heterostructure up to 380 K. In the present example, and as discussed below, field-free, perpendicular magnetization switching by SOT occurs only when the current flows along the zigzag direction of the monolayer Fe:MoS₂ 144 (i.e., the configuration shown in FIGS. 6 and 7B) due to strain-induced crystal asymmetry 144A′ along the armchair direction axis 144B (i.e., the strain is perpendicular to the direction of the write current J_{w}, which is perpendicular to the current flow J_{w} direction. The rotational symmetry breaking in Fe:MoS₂ promotes field-free SOT switching by generating out-of-plane spins via spin-to-spin conversion.

Further discussion regarding details regarding the systems, materials, methods, and devices described herein can be found in “Magnetic Switching in Monolayer 2D Diluted Magnetic Semiconductors via Spin-to-Spin Conversion” by Chen et al., which is hereby incorporated by reference in its entirety and provided in the attached Appendix.

With specific reference to FIGS. 7A and 7B, the field-free, deterministic, non-volatile SOT switching of perpendicular magnetization of the monolayer Fe:MoS₂ can be tested/measured by applying a write current J_{w} along the two different axes (y-axis/armchair direction and x-axis/zigzag direction) based on the angled positioning of the Fe:MoS₂ 144 against the Pt Hall bar 120 (which, as discussed above, induces uniaxial strain in the Fe:MoS₂ 144 while retaining mirror symmetry along the y-axis).

As depicted in FIG. 7A, the magnetization state of Fe:MoS₂ 144 can be initialized to out of plane magnetization (m_{z}), e.g., m_{z}+1, then, J_{w} is applied parallel to the y-axis (J_{w}∥γ), under which it switched to a state with near-zero Hall resistance (m_{z}, R_{H}≈0). For both pulse sweeping directions starting from m_{z}=+1, this m_{z}≈0 state cannot be switched back to m_{z}=+1 by reversing the current direction. This switching behavior can be attributed to either demagnetization of Fe:MoS₂ by Joule heating or switching of the magnetization direction to the in-plane direction (x-direction) by the in-plane torque τ_{AD}^{IP}.

In contrast, when a current J_{w} is applied along the low-symmetry axis, as shown in FIG. 7B, an out-of-plane anti-damping torque τ_{AD}^{OOP} is generated, which allows the magnetization of Fe:MoS₂ to be toggled between m_{z}≈±0.8 upon reversing the current direction. This is consistent with magnetic switching by TApP, in which the magnetization direction can be reversed with a change in the write current direction. This out-of-plane anti-damping torque facilitates field-free SOT switching. The current density in this scenario is approximately one-tenth of the demagnetizing current density needed for J_{w}∥γ. The applied current pulses (1 ms pulse duration) enable the switching of out-of-plane Fe:MoS₂ magnetization at room temperature.

The presence of τ_{AD}^{OOP} in low-symmetry systems, including WTe₂/FM and TaIrTe₄/FM, has previously been determined. τ_{AD}^{OOP} is not necessarily dependent on the direction of magnetization in ferromagnets but rather on the direction of the write current J. This characteristic implies that the out-of-plane magnetization (m_{z}) can be effectively modulated by applying a write current along the x-axis, resulting in a shift in the AHE hysteresis loop.

The temperature dependence of the Hall resistance can be obtained by sweeping the magnetic field. In the present example, antisymmetric humps observed near zero in the Hall resistance can be preserved over a wide temperature range, e.g., from 4 K to 300 K, without a significant shape change. These antisymmetric humps resemble those previously reported for THE in a range of ferromagnetic systems, which possess ferromagnetic order arising from intrinsic origins or doping. A recurring observation in the literature is that the hump location typically coincides with the AHE domain reversal, which can be attributed to either THE or two-channel AHE. Accordingly, the Hall signal may be decomposed into two channels with humps near the domain reversal. In some examples, a first channel (R_{H1}) presents a Hall loop with domain reversal near a first hump at approximately ±0.5 kOe, while the remaining Hall signal (R_{H2}) shows a Hall loop with domain reversal near a second hump at approximately ±2-2.5 kOe.

The THE signal may be closely related to the Dzyaloshinskii-Moriya interaction (DMI)-induced magnetic skyrmions, where moving spin-polarized electrons acquire the skyrmion-induced Berry phase by adjusting their spins to the local spins of the skyrmion texture, giving rise to the observed humps. The presence of an appropriate DMI intensity within an FM/HM system may be crucial in facilitating field-free SOT magnetization switching. This switching process may be initiated by domain nucleation at one edge of the FM, followed by domain wall propagation toward the opposite edge.

It will be appreciated that similar humps can be produced by alternative methods, such as competing ferromagnetic phases caused by interface-induced AHE sign reversal or nonhomogeneous samples. However, in some examples using monolayer Fe:MoS₂, magnetic circular dichroism (MCD) analysis may reveal no visible magnetic subdomains, and photoluminescence (PL) mapping may corroborate the uniformity of the defect luminescence and Fe-related peak. Furthermore, interface-induced sign reversal typically requires two ferromagnetic layers with composition differences, which may not be present when using a monolayer Fe:MoS₂ for the Hall measurement.

Put another way, and with continued reference to the configuration of FIG. 7B, when current pulses are applied in the x-direction of the Fe:MoS₂/Pt Hall bar, the magnetic state of Fe:MoS₂ 144 is toggled between the z+ and z−directions (also referred to herein as a parallel state and an antiparallel state) without needing an external magnetic field. At 380 K, the critical current density applied through the Pt Hall bar 120 is a notably low J_{c}=7×10⁴ A cm⁻². This current density corresponds to a power dissipation density of P_{sw}=7.5×10¹² W m⁻³ (i.e., P_{SW}=J_{c}²ρ, where ρ is the resistivity of the device), which is four orders of magnitude lower than reported vdW SOT materials and three orders of magnitude lower than non-vdW SOT materials.

It will be appreciated by those skilled in the art that the SOT device 100 described herein provides ultralow-power, field-free, deterministic, and nonvolatile perpendicular magnetization switching by SOT up to 380 K using a DMS, monolayer Fe:MoS₂ 144 through interfacial coupling with a Pt Hall bar 120 (or other appropriate heavy metal or topological insulator, as discussed above). Moreover, a switching current density of 7×10⁴ A/cm² is nearly two orders of magnitude lower than reported field-free SOT systems. The power dissipation density of P_{sw}=7.5×10¹² W m⁻³ is four orders of magnitude lower than reported vdW SOT materials and three orders of magnitude lower than non-vdW SOT materials. The magnitude of the antisymmetric humps persists up to 300 K, indicating that robust magnetic textures are stable at the Fe:MoS₂/Pt interface over a wide temperature range. This SOT application using a 2D monolayer DMS provides a new pathway for developing highly power-efficient spintronic devices not previously contemplated in the art.

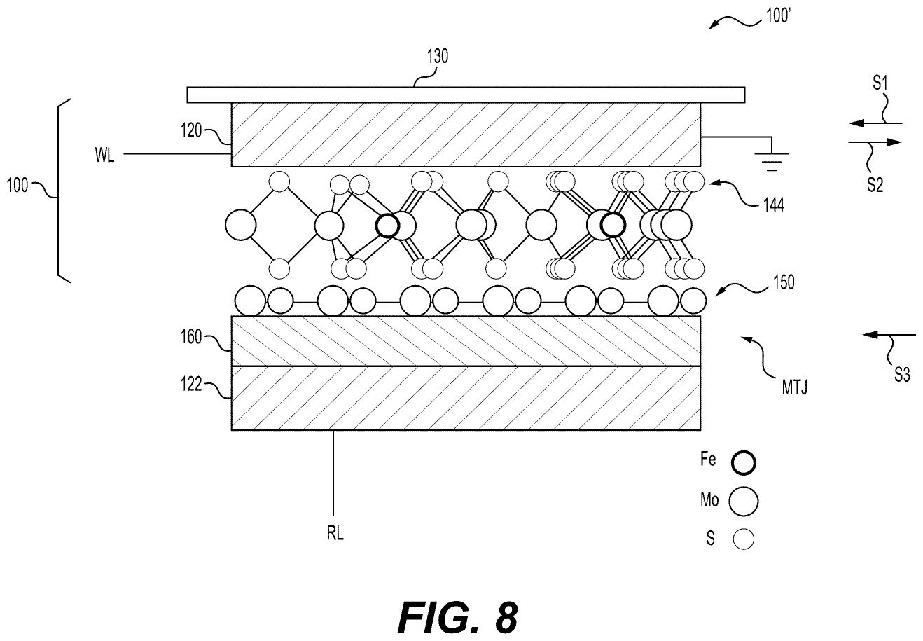

FIG. 8 is one such example of an application of the SOT device 100 described herein. In particular, the SOT device 100 described herein can be used to develop 2D SOT-MRAM devices 100′. While conventional SOT-MRAM devices use a metallic ferromagnet as a free magnetic layer, which demands high energy to change the direction of magnetization, the devices of the presently disclosed technology can use Fe:MoS₂ in 2D SOT-MRAM, which will ensure much lower energy consumption. Furthermore, this 2D SOT-MRAM application provides room temperature and above operation, and can be applied to curved and bendable surfaces.

Specifically, and for example, FIG. 8 depicts a conceptual cross-section of a 2D SOT-MRAM memory cell 100′, which includes a solid-state magnetic memory in the form of a magnetic tunnel junction (MTJ). The SOT-MRAM cell 100′ has a free magnetic layer 144, a fixed magnetic layer 160, and a tunnel barrier 150 (comprising, e.g., a non-magnetic material, hbN, or MgO). The free magnetic layer 144 stores information in its magnetic state. The fixed layer 160 has a permanently oriented direction in a predetermined state and provides a reference frame required for reading and writing. The SOT-MRAM cell 100′ further includes a bottom electrode 120 capable of generating spin currents via the SHE, upon which the free layer 144 is disposed. The bottom electrode 120 can be disposed on a substrate 130 (as discussed in previous figures).

The fabrication methods for integrating Fe:MoS₂ into the device architecture of a SOT-MRAM memory cell have generally been well-established. To fabricate 2D SOT MRAM, the bottom electrode 120 and bottom insulator can be fabricated via standardized lift-off photolithography and sputtering. The free layer 144 (e.g., Fe:MoS₂ monolayer(s)) can be transferred onto the surface with polymer-based methods which have been well-established.

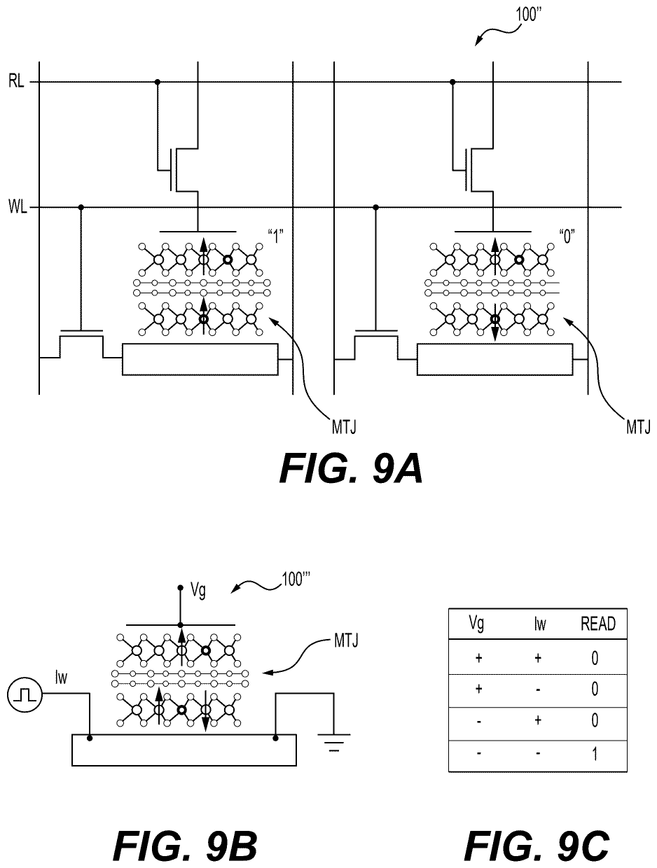

The SOT-MRAM functionality is powered by the tunneling magnetoresistance (TMR) effect for the reading of memory and the SOT effect for the writing to memory. This TMR effect causes the resistance of the MTJ to change dramatically, which enables the magnetic state of the free layer to be sensed and, thus, stored information to be read. FIG. 9 is a schematic illustration of the operating principle of the inventive SOT-MRAM in parallel and antiparallel modalities/states. As discussed above with respect to FIG. 8, the SOT effect between the bottom electrode 120 and the free magnetic layer 144 enables the magnetic state of the free layer 144 to be changed if the torque is sufficiently strong, and thus information can be written. In some examples, the current density is approximately 7×10⁴ A/cm² applied through the bottom electrode 120.

The free layer 144 can be a uniaxially strained 2D magnetic semiconductor layer in accordance with the present disclosure, and the fixed layer 160 can be made of another magnetic layer (in some examples, thicker than that of the free layer 144), which does not switch during the memory operation. The fixed layer can include, for example, Co, Fe, Ni, or Fe:MoS₂. The tunnel barrier 150 is a thin (e.g., about 10 Å) insulating, non-magnetic layer between the free layer 144 and the fixed layer 160. In one example, the insulating layer is crystalline MgO. In other examples, the insulating layer (i.e., tunnel barrier 150) comprises hexagonal boron nitride or multilayer molybdenum disulfide.

In some examples, the free layer 144 of 2D SOT-MRAM can be a monolayer Fe:MoS₂, and the fixed layer 160 can be made of a thicker Fe:MoS₂, or another hard magnetic thin film.

The SOT-MRAM memory cell 100′ can further include a top electrode 122 positioned above the fixed magnetic layer 160 (relative to an opposite orientation of FIG. 9).

The top electrode 122 is made of a conductive material connected with a read line RL and capable of facilitating read current flow (perpendicular relative to the write current flow) through the fixed magnetic layer 160, the tunnel barrier 150, the free magnetic layer 144, and the bottom electrode 120.

In this example, the magnetization direction of the free layer 144 changes (between directions S1 and S2) when a write current J_{w} is applied along the word line WL, while that of the fixed layer (see magnetization direction S3) does not. In this way, the free layer 144 can be configured to have a magnetization direction that is parallel to that of the fixed layer 160 (i.e., S1 and S3), or a magnetization direction that is antiparallel to that of the fixed layer 160 (i.e., S2 and S3). The magnetization direction (S1 or S2) of the free layer 144 can be read by passing a current through the MTJ via a read line RL.

A further example of an SOT-MRAM system can be seen in FIGS. 9A-9C. FIG. 9A is a schematic layout of a 2×1 SOT-MRAM unit. FIG. 9B is a cross-sectional schematic of a spin-logic device based on MRAM unit. FIG. 9C is a logic truth table showing an example of the expected MTJ resistance.

In this example, the previously described field-free, non-volatile SOT switching utilizing a vdW dilute magnetic semiconductor (DMS), Fe:MoS₂. 144 can be used to realize the SOT switching operations for SOT-MRAM units. The data in the SOT-MRAM cell 100″ can be read by measuring the resistance across the MTJ using the TMR effect. The fabricated twisted bilayer Fe:MoS₂/Pt heterostructures can be integrated with tunneling barriers (e.g., hBN or multilayer MoS₂) via a transfer of thin hBN layer or atomic layer deposition of Al₂O₃ and fixed layers via a transfer of Fe:MoS₂ on a tunneling barrier (for SOT-MRAMs, the free and fixed layers can, but do not necessarily need to, be the same materials). As shown in FIG. 9A, a voltage below the SOT switching threshold can be first applied across the MTJ to sense the resistance. Then, the word line (WL) can be selected for writing, and a current can be applied to the bit line to generate a spin current via the SHE. For reading, the target cell's reading line (RL) can be selected, and a current can be applied to the bit line to read the MTJ resistance.

For example, a simple spin-logic device 100′″ based on 2×1 MTJ modulates SOT-induced switching via a gate voltage, which changes the magnetic anisotropy of Fe:MoS₂ via voltage-controlled magnetism. This mechanism enables electric-gating-induced modulation of SOT switching, which is essential for complex logic operations. Making reference to FIG. 9B, the top gate (V_{g}) and writing current (I_{w}) are logic inputs. The SOT switching current can be adjusted by applying the top gate in the MTJ structure. In the scenario shown in FIG. 9B, the I_{w} cannot switch the free layer when V_{g} is positive. Thus, the resistance of the MTJ junction facilitates the AND logic operation. FIG. 9C depicts a logic truth table showing an example of the MTJ resistance using the spin-logic device 100″ of FIG. 9B.

Of course, the presently disclosed technology has other potential applications, and those skilled in the art will appreciate that the foregoing examples are merely to illustrate the principles of the disclosed technology. For example, the disclosed technology can be used to form highly sensitive magnetic sensors, terahertz magneto-optical devices, multiferroics, topological quantum computing, and the like. Specifically, a 2D ferromagnetic semiconductor monolayer as disclosed above can be easily fabricated and integrated into current structures by replacing the free layer with the inventive 2D ferromagnetic semiconductor monolayer. Moreover, besides SOT devices, the technology disclosed herein can also be employed in OT devices. Also, in addition to using TMD monolayers, twisted bilayers can be used to enhance the symmetry breaking of the system.

FIG. 11 depicts a generalized method 1100 of switching a resistance state of a free magnetic layer in an external environment in accordance with the present disclosure. Due to the novel techniques described herein, the method 1100 can be performed in an external environment above room temperature and without an external magnetic field. The method 1100 includes applying 1102 a current through a bottom electrode in a direction that is parallel to a plane of the free magnetic layer that is disposed on the bottom electrode. The method 1100 includes generating 1104 spin currents via the SHE. The method 1100 includes switching 1106, via the spin currents and in the absence of an external magnetic field, a magnetization direction of the free magnetic layer.

In summary, the presently disclosed technology presents a novel SOT device that enables highly energy-efficient, field-free, deterministic, and non-volatile SOT magnetization switching. Specifically, the present application describes a field-free SOT system at up to at least 380 K, the highest temperature ever reported, with a remarkably low switching current density of 7×104 A/cm², nearly two orders of magnitude lower than reported field-free SOT systems. The present application also discloses SOT switching using a DMS at the true 2D limit (i.e., with atomically thin monolayers), thus paving the way for practical spintronic memory devices with high-density and low power consumption.

The disclosed technology described herein can be further understood according to the following clauses:

Clause 1. A spin-orbit-torque (SOT) device, comprising: a bottom electrode capable of generating spin currents via the spin Hall effect (SHE); and a free magnetic layer disposed on the bottom electrode, a magnetization of the free magnetic layer being switchable by the spin currents between, relative to the predetermined state, a parallel state and an antiparallel state in the absence of an external magnetic field, the free magnetic layer comprising a van der Waals (vdW) dilute magnetic semiconductor having a Curie Temperature greater than room temperature.

Clause 2. The SOT device of clause 1, the free magnetic layer having a Curie Temperature up to at least 380 Kelvin.

Clause 3. The SOT device of any one of clauses 1-2, the magnetization of the free magnetic layer being configured to switch between the parallel state and the antiparallel state in response to a current density of approximately 7×10⁴ A/cm² applied through the bottom electrode.

Clause 4. The SOT device of any one of clauses 1-3, the free magnetic layer comprising a two-dimensional transition metal-doped transition metal dichalcogenide monolayer.

Clause 5. The SOT device of clause 4, the monolayer comprising molybdenum disulfide including iron dopants (Fe:MoS₂) or tungsten diselenide including iron dopants (Fe:WSe₂).

Clause 6. The SOT device of any one of clauses 1-5, the free magnetic layer being atomically thin.

Clause 7. The SOT device of any one of clauses 1-6, the free magnetic layer being uniaxially strained in a direction that is perpendicular to a height direction of the bottom electrode.

Clause 8. The SOT device of any one of clauses 1-7, the bottom electrode comprising: a heavy metal layer comprising platinum (Pt), tantalum (Ta) or tungsten (W).

Clause 9. The SOT device of any one of clauses 1-8, further comprising: a fixed magnetic layer, a magnetization of the fixed magnetic layer being permanently oriented in a predetermined state; and a tunnel barrier disposed between the fixed magnetic layer and the free magnetic layer, forming a magnetic tunnel junction (MTJ).

Clause 10. The SOT device of any one of clauses 1-9, the fixed magnetic layer comprising a ferromagnetic material selected from the group consisting of cobalt (Co), iron (Fe), nickel (Ni), and multilayer molybdenum disulfide with iron dopants (Fe:MoS₂).

Clause 11. The SOT device of any one of clauses 1-10, the fixed magnetic layer comprising a thickness greater than the thickness of the free magnetic layer.

Clause 12. The SOT device of any one of clauses 1-11, the tunnel barrier comprising magnesium oxide (MgO), multilayer molybdenum disulfide (MoS₂), or hexagonal boron nitride (hBN).

Clause 13. The SOT device of any one of clauses 1-12, the tunnel barrier comprising a thickness of approximately 10 Angstroms.

Clause 14. The SOT device of any one of clauses 1-13, further comprising a top electrode positioned above the fixed magnetic layer, the top electrode being made of a conductive material capable of facilitating read current flow through the fixed magnetic layer, the tunnel barrier, the free magnetic layer, and the bottom electrode.

Clause 15. The SOT device of any one of clauses 1-14, further comprising: a word line electrically connected to the bottom electrode, the word line being configured to carry a write current that passes through the bottom electrode to generate the spin currents in the bottom electrode to switch the magnetization of the free magnetic layer; and a read line electrically connected to the magnetic tunnel junction, the read line being configured to carry a read current passing through the MTJ to detect a resistance state of the MTJ, the read current passing through the MTJ being orthogonal to the write current passing through the bottom electrode.

Clause 16. The SOT device of any one of clauses 1-15, further comprising a substrate, the bottom electrode being disposed on the substrate.

Clause 17. The SOT device of clause 16, the substrate comprising a dielectric layer.

Clause 18. A SOT device, comprising: a bottom electrode comprising a heavy metal layer capable of generating spin currents via the spin Hall effect (SHE); and a free magnetic layer disposed on the bottom electrode, a magnetization of the free magnetic layer being switchable by the spin currents between, relative to the predetermined state, a parallel state and an antiparallel state, the free magnetic layer comprising molybdenum disulfide including iron dopants (Fe:MoS₂).

Clause 19. The SOT device of clause 18, the magnetization of the free magnetic layer being switchable by the spin currents between the parallel state and the antiparallel state in the absence of an external magnetic field.

Clause 20. The SOT device of any one of clauses 18-19, the free magnetic layer having a Curie Temperature greater than room temperature.

Clause 21. The SOT device of clause 20, the free magnetic layer having a Curie Temperature up to 380 Kelvin.

Clause 22. The SOT device of any one of clauses 18-21, the magnetization of the free magnetic layer being configured to switch between the parallel state and the antiparallel state in response to a current density of approximately 7×10⁴ A/cm² applied through the bottom electrode.

Clause 23. The SOT device of any one of clauses 18-22, the free magnetic layer being atomically thin.

Clause 24. The SOT device of any one of clauses 18-23, the bottom electrode comprising: a heavy metal layer comprising Pt, Ta, or W.

Clause 25. The SOT device of any one of clauses 18-24, further comprising: a fixed magnetic layer, a magnetization of the fixed magnetic layer being permanently oriented in a predetermined state; and a tunnel barrier disposed between the fixed magnetic layer and the free magnetic layer, forming a magnetic tunnel junction (MTJ).

Clause 26. The SOT device of any one of clauses 18-25, the fixed magnetic layer comprising a ferromagnetic material selected from the group consisting of Co, Fe, Ni, and multilayer molybdenum disulfide including iron dopants (Fe:MoS₂).

Clause 27. The SOT device of any one of clauses 18-26, the fixed magnetic layer comprising a thickness greater than a thickness of the free layer.

Clause 28. The SOT device of any one of clauses 18-27, the tunnel barrier comprising MgO, MoS₂, or hBN.

Clause 29. The SOT device of any one of clauses 18-28, the tunnel barrier comprising a thickness of approximately 10 Angstroms.

Clause 30. The SOT device of any one of clauses 18-29, further comprising a top electrode positioned above the magnetic layer, the top electrode being made of a conductive material capable of facilitating read current flow through the fixed magnetic layer, the tunnel barrier, the free magnetic layer, and the bottom electrode.

Clause 31. A method of switching a resistance state of a free magnetic layer in an external environment, the external environment comprising a temperature at or greater than room temperature, the method comprising: applying a current through a bottom electrode in a direction that is parallel to a plane of the free magnetic layer that is disposed on the bottom electrode; generating spin currents via the SHE; and switching, via the spin currents and in the absence of an external magnetic field, a magnetization direction of the free magnetic layer.

Clause 32. A method of making a SOT device, comprising: producing a first semiconductor material, the producing comprising: growing a two-dimensional transition metal dichalcogenide monolayer on a first substrate; and adding a dopant to the monolayer while the monolayer is being grown on the first substrate; patterning a heavy metal layer onto a second substrate; transferring the first semiconductor material onto the heavy metal layer; and inducing uniaxial strain in the first semiconductor material in a direction that is (i) perpendicular to a height direction of the heavy metal layer, and (ii) perpendicular to a direction in which write current is configured to flow through the heavy metal layer.

The examples described above are cited by way of example, and the disclosed technology is not limited by what has been particularly shown and described hereinabove.

Rather, the scope of the disclosed technology includes both combinations and sub combinations of the various features described hereinabove, as well as variations and modifications thereof which would occur to persons skilled in the art upon reading the foregoing description and which are not disclosed in the prior art.

What is claimed is:

1. A spin-orbit-torque (SOT) device, comprising:
a bottom electrode capable of generating spin currents via the spin Hall effect (SHE); and
a free magnetic layer disposed on the bottom electrode, a magnetization of the free magnetic layer being switchable by the spin currents between, relative to the predetermined state, a parallel state and an antiparallel state in the absence of an external magnetic field, the free magnetic layer comprising a van der Waals (vdW) dilute magnetic semiconductor having a Curie Temperature greater than room temperature.

2. The SOT device of claim 1, the free magnetic layer having a Curie Temperature up to at least 380 Kelvin.

3. The SOT device of claim 1, the magnetization of the free magnetic layer being configured to switch between the parallel state and the antiparallel state in response to a current density of approximately 7×10⁴ A/cm² applied through the bottom electrode.

4. The SOT device of claim 1, the free magnetic layer comprising a two-dimensional transition metal-doped transition metal dichalcogenide monolayer.

5. The SOT device of claim 4, the monolayer comprising molybdenum disulfide including iron dopants (Fe:MoS₂) or tungsten diselenide including iron dopants (Fe:WSe₂).

6. The SOT device of claim 1, the free magnetic layer being atomically thin.

7. The SOT device of claim 1, the free magnetic layer being uniaxially strained in a direction that is perpendicular to a height direction of the bottom electrode.

8. The SOT device of claim 1, the bottom electrode comprising:
a heavy metal layer comprising platinum (Pt), tantalum (Ta) or tungsten (W).

9. The SOT device of claim 1, further comprising:
a fixed magnetic layer, a magnetization of the fixed magnetic layer being permanently oriented in a predetermined state; and
a tunnel barrier disposed between the fixed magnetic layer and the free magnetic layer, forming a magnetic tunnel junction (MTJ).

10. The SOT device of claim 1, the fixed magnetic layer comprising a ferromagnetic material selected from the group consisting of cobalt (Co), iron (Fe), nickel (Ni), and multilayer molybdenum disulfide with iron dopants (Fe:MoS₂).

11. The SOT device of claim 1, the fixed magnetic layer comprising a thickness greater than the thickness of the free magnetic layer.

12. The SOT device of claim 1, the tunnel barrier comprising magnesium oxide (MgO), multilayer molybdenum disulfide (MoS₂), or hexagonal boron nitride (hBN).

13. The SOT device of claim 1, the tunnel barrier comprising a thickness of approximately 10 ångströms.

14. The SOT device of claim 1, further comprising a top electrode positioned above the fixed magnetic layer, the top electrode being made of a conductive material capable of facilitating read current flow through the fixed magnetic layer, the tunnel barrier, the free magnetic layer, and the bottom electrode.

15. The SOT device of claim 1, further comprising:
a word line electrically connected to the bottom electrode, the word line being configured to carry a write current that passes through the bottom electrode to generate the spin currents in the bottom electrode to switch the magnetization of the free magnetic layer; and
a read line electrically connected to the magnetic tunnel junction, the read line being configured to carry a read current passing through the MTJ to detect a resistance state of the MTJ, the read current passing through the MTJ being orthogonal to the write current passing through the bottom electrode.

16. The SOT device of claim 1, further comprising a substrate, the bottom electrode being disposed on the substrate.

17. The SOT device of claim 16, the substrate comprising a dielectric layer.

18. A SOT device, comprising:
a bottom electrode comprising a heavy metal layer capable of generating spin currents via the spin Hall effect (SHE); and
a free magnetic layer disposed on the bottom electrode, a magnetization of the free magnetic layer being switchable by the spin currents between, relative to the predetermined state, a parallel state and an antiparallel state, the free magnetic layer comprising molybdenum disulfide including iron dopants (Fe:MoS₂).

19. The SOT device of claim 18, the magnetization of the free magnetic layer being switchable by the spin currents between the parallel state and the antiparallel state in the absence of an external magnetic field.

20. The SOT device of claim 18, the free magnetic layer having a Curie Temperature greater than room temperature.
